(19) United States
(12) Patent Application Publication
(10) Pub. No.: US 2008/0118999 A1
(43) Pub. Date: May 22, 2008

(54) METHOD OF FABRICATING A NITRIDE SEMICONDUCTOR LIGHT EMITTING DEVICE

(75) Inventor: Satoshi Komada, Mihara-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/941,442

(22) Filed: Nov. 16, 2007

(30) Foreign Application Priority Data
Nov. 22, 2006 (JP) 2006-315296

(51) Int. Cl. H01L 33/00

(52) U.S. Cl. 438/46; 257/E33.025

(57) ABSTRACT

A method of fabricating a nitride semiconductor light emitting device includes the steps of: depositing on a substrate a first n-type nitride semiconductor layer, a light emitting layer, a p-type nitride semiconductor layer, and p-type nitride semiconductor tunnel junction layer containing an indium, in this order; depositing a nitride semiconductor evaporation reduction layer on the p-type nitride semiconductor tunnel junction layer at the temperature of the substrate which is at most a temperature higher by 150° C. than that of the substrate in depositing the p-type nitride semiconductor tunnel junction layer, the nitride semiconductor evaporation reduction layer having a band gap larger than that of the p-type nitride semiconductor tunnel junction layer; and depositing a second n-type nitride semiconductor layer on the nitride semiconductor evaporation reduction layer at the temperature of the substrate which is higher than that of the substrate in depositing the nitride semiconductor evaporation reduction layer.

This nonprovisional application is based on Japanese Patent Application No. 2006-315296 filed with the Japan Patent Office on Nov. 22, 2006, the entire contents of which are hereby incorporated by reference.

### BACKGROUND OF THE INVENTION

1. Field of the Invention

The present invention relates generally to methods of fabricating nitride semiconductor light emitting devices and particularly to methods of fabricating nitride semiconductor light emitting devices having a tunnel junction.

2. Description of the Background Art

Conventionally a nitride semiconductor light emitting diode device including a p-type nitride semiconductor layer having a side serving as a light extraction side is required to have a p-side electrode provided on the p-type nitride semiconductor layer to satisfy the following three conditions:

A first condition is that the p-side electrode is highly transmissive for light emitted from the nitride semiconductor light emitting diode device. A second condition is that the p-side electrode has a resistivity and a thickness allowing an injected current to be diffused sufficiently in a plane of a light emitting layer. Finally, a third condition is that the p-side electrode has a small contact resistance between the electrode and the p-type nitride semiconductor layer.

The p-side electrode formed on the p-type nitride semiconductor layer of the nitride semiconductor light emitting diode device with the p-type nitride semiconductor layer having a side serving as a light extraction side has conventionally been implemented as a semitransparent metal electrode formed of palladium, nickel or similar metal film deposited on the entire surface of the p-type nitride semiconductor layer. However, such a semitransparent metal electrode has as low a transmittance as approximately 50% for light emitted from the nitride semiconductor light emitting diode device. As a result the nitride semiconductor light emitting diode device extracts light less efficiently and thus cannot be a high-luminance nitride semiconductor light emitting diode device.

To address this issue a high-luminance nitride semiconductor light emitting diode device is fabricated so as to replace the semitransparent metal electrode of palladium, nickel or similar metal film with a transparent conductive film of indium tin oxide (ITO) deposited on the entire surface of a p-type nitride semiconductor layer to extract light more efficiently. The nitride semiconductor light emitting diode device having such transparent conductive film also allows the concerned contact resistance between the transparent conductive film and the p-type nitride semiconductor layer to be reduced by a thermal treatment or the like.

Furthermore, Japanese Patent Laying-open No. 2002-319703 discloses a nitride semiconductor light emitting diode device including a p-type nitride semiconductor layer, an n-type nitride semiconductor layer overlying and cooperating with the p-type nitride semiconductor layer to provide a tunnel junction, and a p-side electrode overlying the n-type nitride semiconductor layer. The nitride semiconductor light emitting diode device thus configured can extract light more efficiently as it allows a current injected from the p-side electrode to be widen in the low-resistance n-type nitride semiconductor layer forming the tunnel junction.

### SUMMARY OF THE INVENTION

However, when the transparent conductive film of ITO is increased in temperature to have high temperature it has an optical property irreversively varied, resulting in a reduced transmittance for visible light. Furthermore, when the transparent conductive film of ITO is used, in order to prevent the film from reducing the transmittance for visible light, the temperature range in a process after the formation of the transparent conductive film of ITO is limited. Furthermore, the transparent conductive film of ITO is also impaired by an operation with a large current density and blackened.

Furthermore, such nitride semiconductor light emitting diode device having a tunnel junction as described in Japanese Patent Laying-open No. 2002-319703 allows a carrier to tunnel through the tunnel junction at a probability as represented generally by the following expression:

Tt=exp((−8π(2mₑ)^{1/2}Eg^{3/2})/(3qhε)) (1),

wherein
Tt: probability of tunneling,
mₑ: effective mass of conduction electron,
Eg: energy gap,
q: charge of electron,
h: Plank's constant, and
ε: electric field applied to tunnel junction.

As represented in expression (1), to increase the probability of tunneling Tt and achieve a reduced loss in voltage at the tunnel junction, initially it is necessary to increase electric field ε applied to the tunnel junction, and to increase electric field ε, it is necessary to provide an increased ionized impurity concentration in the n-type nitride semiconductor layer and the p-type nitride semiconductor layer at their respective portions forming the tunnel junction.

However, nitride semiconductor provides an acceptor level that is provided by magnesium, which is generally used as a p-type dopant, deep with respect to its valence band, and has a small activation ratio. It is thus difficult to obtain a p-type nitride semiconductor having a high ionized impurity concentration.

Furthermore, as represented in expression (1), to increase the probability of tunneling Tt, it is also necessary to decrease energy gap Eg of the tunnel junction.

With the above circumstances considered, the most preferable configuration of those described in Japanese Patent Laying-open No. 2002-319703 would be that described for example in a fourth example and the like providing a tunnel junction having a p-type In_{0.18}Ga_{0.82}N layer having a carrier density of 1×10¹⁹/cm³ and an n-type In_{0.18}Ga_{0.82}N layer having a carrier density of 1×10²⁰/cm³.

In theses examples, however, after the n-type In_{0.18}Ga_{0.82}N layer is provided the intermediate product is heated to a high temperature of 1050° C., when the p-type In_{0.18}Ga_{0.82}N layer and n-type In_{0.18}Ga_{0.82}N layer forming the tunnel junction have a constituent of indium (In) evaporated therefrom. This increases the tunnel junction's energy gap Eg, which in turn provides a decreased probability of tunneling and hence an increased loss in voltage at the tunnel junction, resulting in an increased driving voltage.

Furthermore, if the tunnel junction is formed of a p-type InGaN layer and an n-type InGaN layer each having an In content ratio increased to provide an increased probability of tunneling, the p-type InGaN layer and n-type InGaN layer forming the tunnel junction would have a band gap smaller than that of a light emitting layer and absorb light emitted from the light emitting layer, and the device thus extracts light less efficiently.

In view of the above circumstances, the present invention contemplates a method of fabricating a nitride semiconductor light emitting device, that can reduce the driving voltage of a nitride semiconductor light emitting device having a tunnel junction and also extract light more efficiently.

The present method is a method of fabricating a nitride semiconductor light emitting device, including the steps of: depositing on a substrate a first n-type nitride semiconductor layer, a light emitting layer, a p-type nitride semiconductor layer, and a p-type nitride semiconductor tunnel junction layer containing indium, in this order; depositing a nitride semiconductor evaporation reduction layer on the p-type nitride semiconductor tunnel junction layer, at the temperature of the substrate which is at most a temperature higher by 150° C. than that of the substrate in depositing the p-type nitride semiconductor tunnel junction layer, the nitride semiconductor evaporation reduction layer having a band gap larger than that of the p-type nitride semiconductor tunnel junction layer; and depositing a second n-type nitride semiconductor layer on the nitride semiconductor evaporation reduction layer, at the temperature of the substrate which is higher than that of the substrate in depositing the nitride semiconductor evaporation reduction layer.

Furthermore in the present method an n-type nitride semiconductor tunnel junction layer can be deposited on the p-type nitride semiconductor tunnel junction layer to cooperate therewith to form a tunnel junction and the nitride semiconductor evaporation reduction layer can thereafter be deposited on the n-type nitride semiconductor tunnel junction layer.

Furthermore in the present method preferably the second n-type nitride semiconductor layer is deposited at the temperature of the substrate which is at least 900° C. and at most 1000° C.

Furthermore in the present method preferably the nitride semiconductor evaporation reduction layer is at least 5 nm in thickness.

The present invention can thus provide a method of fabricating a nitride semiconductor light emitting device, that can reduce the driving voltage of a nitride semiconductor light emitting device having a tunnel junction and also extract light more efficiently.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1-9 are schematic cross sections for illustrating a process of one example of a method of fabricating a nitride semiconductor light emitting device in accordance with the present invention.

FIG. 10 shows one example of the variation of the temperature of the substrate in the method of fabricating a nitride semiconductor light emitting device in accordance with the present invention in the growth from a p-type nitride semiconductor layer to a second n-type nitride semiconductor layer.

FIG. 11 is a schematic cross section of nitride semiconductor light emitting diode devices in first to third examples.

FIG. 12 shows a relationship between the temperature of a sapphire substrate in growing an n-type GaN evaporation reduction layer of the nitride semiconductor light emitting diode device of the first example and the driving voltage of the device.

FIG. 13 shows a relationship between the temperature of a sapphire substrate in growing an n-type GaN layer of the nitride semiconductor light emitting diode device of the second example and the driving voltage of the device.

FIG. 14 shows a relationship between the temperature of a sapphire substrate in growing an n-type GaN layer of the nitride semiconductor light emitting diode device of the second example and the optical output of the device.

FIG. 15 shows a relationship between the thickness of an n-type GaN evaporation reduction layer of the nitride semiconductor light emitting diode device of the third example and the driving voltage of the device.

### DESCRIPTION OF THE PREFERRED EMBODIMENTS

Hereinafter one example of the present method of fabricating a nitride semiconductor light emitting device will be described. In the drawings, identical reference characters denote identical or like components and the like.

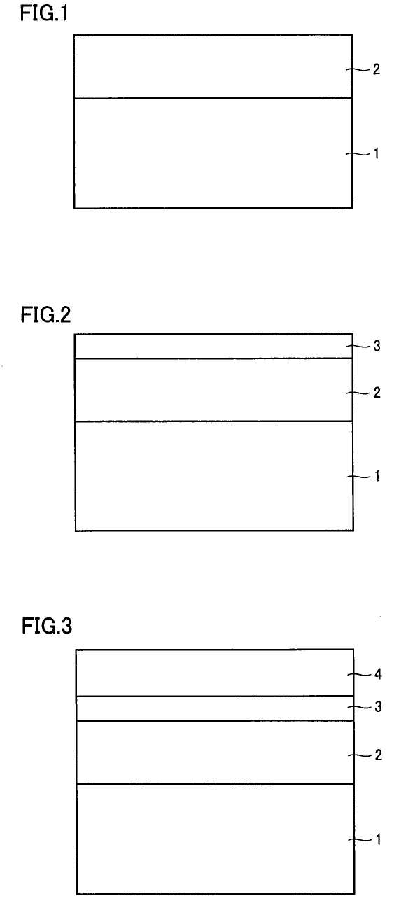

Initially, as shown in FIG. 1, on a substrate 1 a first n-type nitride semiconductor layer 2 is grown for example by metal organic chemical vapor deposition (MOCVD). Substrate 1 can for example be a silicon substrate, a gallium arsenide substrate, a silicon carbide substrate, a zinc oxide substrate, a sapphire substrate, or the like. As first n-type nitride semiconductor layer 2, for example a nitride semiconductor crystal doped with an n-type impurity can be grown. Note that in the present invention an n-type impurity can be provided for example by silicon (Si), germanium (Ge) or the like. Furthermore between substrate 1 and first n-type nitride semiconductor layer 2 there may be interposed for example a low-temperature buffer layer formed of nitride semiconductor and/or an undoped nitride semiconductor or other similar layer.

Subsequently, as shown in FIG. 2, on first n-type nitride semiconductor layer 2 a light emitting layer 3 is grown for example by MOCVD. As light emitting layer 3, for example a nitride semiconductor crystal having a single quantum well (SQW) structure or a multi quantum well (MQW) structure can be grown. Representatively, a stack of an InₓGa₁₋ₓN layer and an In_{y}Ga_{1-y}N layer can be grown, wherein 0<x<1, 0≦y<0.2, and x>y. Furthermore between first n-type nitride semiconductor layer 2 and light emitting layer 3 another layer may be provided.

Subsequently, as shown in FIG. 3, on light emitting layer 3 a p-type nitride semiconductor layer 4 is grown for example by MOCVD. As p-type nitride semiconductor layer 4, for example a nitride semiconductor crystal doped with a p-type impurity can be grown. Representatively, a p-type Al_{z}Ga_{1-z}N layer or a p-type GaN layer or the like can be grown, wherein 0<z<1. Note that in the present invention as a p-type impurity for example magnesium (Mg), zinc (Zn) or the like can be used. Between light emitting layer 3 and p-type nitride semiconductor layer 4 another layer may be provided.

Subsequently, as shown in FIG. 4, on p-type nitride semiconductor layer 4 a p-type nitride semiconductor tunnel junction layer 5 containing In is grown for example by MOCVD. As p-type nitride semiconductor tunnel junction layer 5, for example a nitride semiconductor crystal of a group III element doped with Mg or a similar p-type impurity can be grown. Between p-type nitride semiconductor layer 4 and p-type nitride semiconductor tunnel junction layer 5 another layer may be provided.

Subsequently, as shown in FIG. 5, on p-type nitride semiconductor tunnel junction layer 5 an n-type nitride semiconductor tunnel junction layer 6 is grown for example by MOCVD. As n-type nitride semiconductor tunnel junction layer 6, for example a nitride semiconductor crystal doped with an n-type impurity can be grown and n-type nitride semiconductor tunnel junction layer 6 cooperates with p-type nitride semiconductor tunnel junction layer 5 to form a tunnel junction.

N-type nitride semiconductor tunnel junction layer 6 can have a donor level shallowed to provide an ionized impurity at a concentration of preferably at least 1×10¹⁹/cm³, more preferably at least 5×10¹⁹/cm³. This allows a depletion layer to extend toward n-type nitride semiconductor tunnel junction layer 6 only for at most a few nm. Thus n-type nitride semiconductor tunnel junction layer 6 can sufficiently exhibit a function as a tunnel junction layer with a thickness of approximately a few nm. It is thus conceived that such reduced thickness ensures that light can be extracted efficiently while providing a reduced energy gap to provide an increased probability of tunneling.

Note that while n-type nitride semiconductor tunnel junction layer 6 may be doped with an n-type impurity alone, it may be doped with a p-type impurity together with the n-type impurity. The p-type impurity introduced as dopant together with the n-type impurity can prevent the directly underlying p-type nitride semiconductor tunnel junction layer 5 from deteriorating in crystallinity as the layer has a p-type impurity diffusing therefrom, and also provide an energy level in a depletion layer to provide an increased probability of tunneling.

Subsequently, as shown in FIG. 6, on n-type nitride semiconductor tunnel junction layer 6 an n-type nitride semiconductor evaporation reduction layer 7 is grown for example by MOCVD to reduce In evaporating from p-type nitride semiconductor tunnel junction layer 5 and n-type nitride semiconductor tunnel junction layer 6. N-type nitride semiconductor evaporation reduction layer 7 has a band gap lager than p-type nitride semiconductor tunnel junction layer 5 and n-type nitride semiconductor tunnel junction layer 6 do, and is grown at the temperature of the substrate which is at most a temperature higher by 150° C. than that of the substrate in growing p-type nitride semiconductor tunnel junction layer 5 and n-type nitride semiconductor tunnel junction layer 6.

For example if p-type nitride semiconductor tunnel junction layer 5 is a Mg-doped, p-type InGaN layer, larger In content ratios allow higher Mg activation ratios. Thus a high ionized impurity concentration can be obtained for a Mg doping concentration and electric field ε applied to the tunnel junction in expression (1) can be increased. Furthermore, larger In content ratios of p-type nitride semiconductor tunnel junction layer 5 and n-type nitride semiconductor tunnel junction layer 6, respectively, can reduce energy gap Eg in expression (1), and by increasing electric field ε that is applied to the tunnel junction in expression (1), and reducing energy gap Eg, the probability of tunneling Tt in expression (1) can be increased.

However, if p-type nitride semiconductor tunnel junction layer 5 and n-type nitride semiconductor tunnel junction layer 6 have their respective In content ratios increased and accordingly have their respective band gaps smaller than that of light emitting layer 3, p-type nitride semiconductor tunnel junction layer 5 and n-type nitride semiconductor tunnel junction layer 6 absorb light emitted from light emitting layer 3 and as a result the device extracts light less efficiently. Accordingly, p-type nitride semiconductor tunnel junction layer 5 and n-type nitride semiconductor tunnel junction layer 6 are preferably as small in thickness as possible.

Thus n-type nitride semiconductor evaporation reduction layer 7 deposited on n-type nitride semiconductor tunnel junction layer 6, as provided in the present invention, can reduce In evaporating from p-type nitride semiconductor tunnel junction layer 5 and n-type nitride semiconductor tunnel junction layer 6. This allows p-type nitride semiconductor tunnel junction layer 5 and n-type nitride semiconductor tunnel junction layer 6 reduced in thickness to still maintain a high In content ratio increasing the probability of tunneling Tt.

The present invention can thus provide a device that can achieve a smaller loss in voltage at a tunnel junction and hence a smaller driving voltage than a device without n-type nitride semiconductor evaporation reduction layer 7, as described in Japanese Patent Laying-open No. 2002-319703.

Furthermore, in the present invention, n-type nitride semiconductor evaporation reduction layer 7 has a band gap larger than p-type nitride semiconductor tunnel junction layer 5 and n-type nitride semiconductor tunnel junction layer 6 do. As such, the light that is not absorbed by p-type nitride semiconductor tunnel junction layer 5 and n-type nitride semiconductor tunnel junction layer 6 is also hardly absorbed by n-type nitride semiconductor evaporation reduction layer 7. The present invention can thus provide a device that can extract light more efficiently.

Furthermore, to reduce In evaporating from p-type nitride semiconductor tunnel junction layer 5 and n-type nitride semiconductor tunnel junction layer 6, it is necessary to grow n-type nitride semiconductor evaporation reduction layer 7 at the temperature of the substrate which is at most a temperature higher by 150° C. than that of the substrate in growing p-type nitride semiconductor tunnel junction layer 5 and n-type nitride semiconductor tunnel junction layer 6. Furthermore, to improve n-type nitride semiconductor evaporation reduction layer 7 in crystallinity, n-type nitride semiconductor evaporation reduction layer 7 is grown preferably with the substrate having a temperature having a lower limit equal to the temperature of the substrate in growing p-type nitride semiconductor tunnel junction layer 5 and n-type nitride semiconductor tunnel junction layer 6.

As n-type nitride semiconductor evaporation reduction layer 7, for example a nitride semiconductor crystal can be grown. Representatively, n-type GaN or n-type InGaN can be grown.

Furthermore, if n-type nitride semiconductor evaporation reduction layer 7 is formed of n-type GaN, then in view of reducing In evaporating from p-type nitride semiconductor tunnel junction layer 5 and n-type nitride semiconductor tunnel junction layer 6, n-type nitride semiconductor evaporation reduction layer 7 preferably has a thickness of at least 5 nm.

In the above description, n-type nitride semiconductor evaporation reduction layer 7 is grown on n-type nitride semiconductor tunnel junction layer 6. Alternatively, n-type nitride semiconductor evaporation reduction layer 7 may be grown on p-type nitride semiconductor tunnel junction layer 5 containing In to allow p-type nitride semiconductor tunnel junction layer 5 and n-type nitride semiconductor evaporation reduction layer 7 to form a tunnel junction. N-type nitride semiconductor evaporation reduction layer 7 in this case also has a band gap larger than that of p-type nitride semiconductor tunnel junction layer 5.

Subsequently, as shown in FIG. 7, on n-type nitride semiconductor evaporation reduction layer 7 a second n-type nitride semiconductor layer 8 is grown for example by MOCVD at the temperature of the substrate which is higher than that of the substrate in growing n-type nitride semiconductor evaporation reduction layer 7. Between n-type nitride semiconductor evaporation reduction layer 7 and second n-type nitride semiconductor layer 8 another layer may be provided.

As second n-type nitride semiconductor layer 8, for example a nitride semiconductor crystal of a group III element doped with an n-type impurity can be grown. Among others, second n-type nitride semiconductor layer 8 preferably has a band gap larger than that of active layer 3 and/or is preferably small in resistivity as a layer to diffuse an injected current and transmit light.

Furthermore, to improve second n-type nitride semiconductor layer 8 in crystallinity and allow the layer to be small in resistivity, second n-type nitride semiconductor layer 8 is grown preferably at the temperature of the substrate which is higher than that of the substrate in growing p-type nitride semiconductor tunnel junction layer 5, n-type nitride semiconductor tunnel junction layer 6 and n-type nitride semiconductor evaporation reduction layer 7. Preferably, second n-type nitride semiconductor layer 8 is grown at the temperature of the substrate which is at least 900° C. and at most 1000° C.

Growing n-type nitride semiconductor evaporation reduction layer 7 at the temperature of the substrate which is higher than 1000° C. may impair light emitting layer 3 in crystallinity, resulting in poor emission efficiency. Growing n-type nitride semiconductor evaporation reduction layer 7 at the temperature of the substrate which is lower than 900° C. may impair second n-type nitride semiconductor layer 8 in crystallinity and also increase the layer in resistance.

Subsequently, as shown in FIG. 8, an etching is performed to expose a portion of a surface of first n-type nitride semiconductor layer 2.

Subsequently, as shown in FIG. 9, a p-side electrode 12 serving as a positive electrode is provided on second n-type nitride semiconductor layer 8 and an n-side electrode 13 serving as a negative electrode is provided on a surface of first n-type nitride semiconductor layer 2.

After p-side electrode 12 and n-side electrode 13 are provided, the wafer is divided into a plurality of chips to obtain a nitride semiconductor light emitting device.

The nitride semiconductor light emitting device fabricated in accordance with the present invention allows n-type nitride semiconductor evaporation reduction layer 7 to reduce In evaporating from p-type nitride semiconductor tunnel junction layer 5 and n-type nitride semiconductor tunnel junction layer 6. This allows p-type nitride semiconductor tunnel junction layer 5 and n-type nitride semiconductor tunnel junction layer 6 to have a high In content and a reduced thickness. A device with reduced driving voltage and high light extraction efficiency can thus be provided.

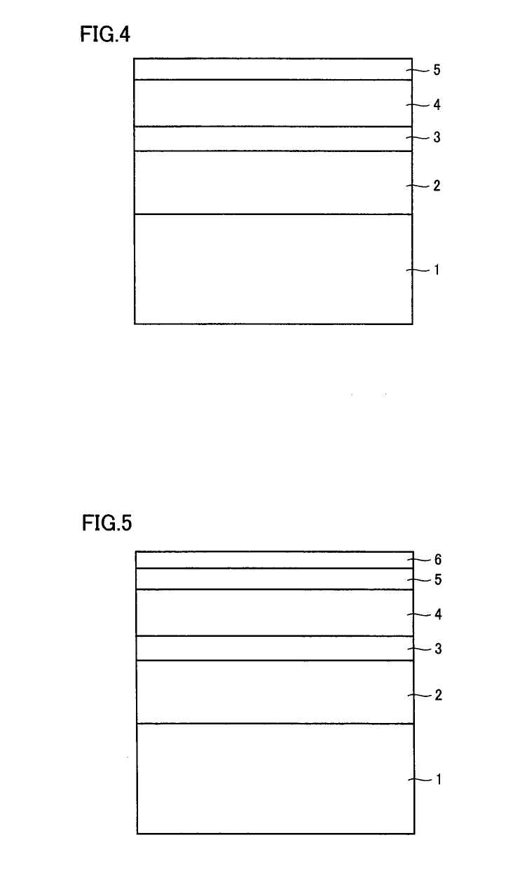

FIG. 10 shows one example of the variation of the temperature of the substrate in growth from p-type nitride semiconductor layer 4 to second n-type nitride semiconductor layer 8. In FIG. 10, the horizontal axis represents the layers in thickness and as it proceeds rightwards a layer is farther away from substrate 1, and the vertical axis represents the temperature of the substrate and as it proceeds upwards it indicates that the temperature of the substrate is higher and as it proceeds downwards it indicates that the temperature of the substrate is lower.

Herein n-type nitride semiconductor evaporation reduction layer 7 is grown with the temperature of the substrate which ranges from the same temperature of the substrate in growing p-type nitride semiconductor tunnel junction layer 5 to that of the substrate 150° C. higher than that of the substrate in growing p-type nitride semiconductor tunnel junction layer 5, and second n-type nitride semiconductor layer 8 is grown at the temperature of the substrate which ranges from at least 900° C. to at most 1000° C.

### FIRST EXAMPLE

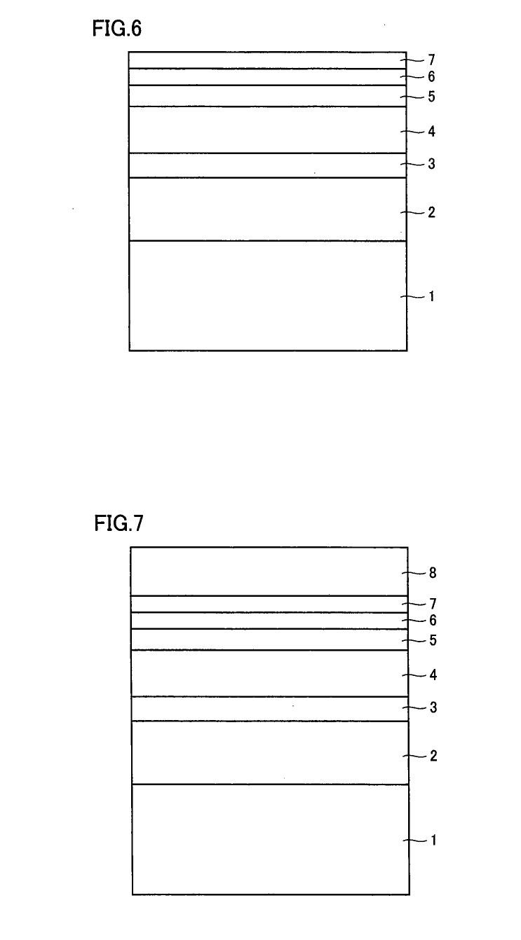

The first example provides the nitride semiconductor light emitting diode device configured as shown in FIG. 11. The first example's nitride semiconductor light emitting diode device includes, a GaN buffer layer 102, an n-type GaN underlying layer 103, an n-type GaN contact layer 104, a light emitting layer 105, a p-type AlGaN clad layer 106, a p-type GaN layer 107, a p-type InGaN tunnel junction layer 108, an n-type InGaN tunnel junction layer 109, an n-type GaN evaporation reduction layer 110, and an n-type GaN layer 111, deposited on a sapphire substrate 101 in this order and a pad electrode 112 deposited on a surface of n-type GaN layer 111 and a pad electrode 113 deposited on a surface of n-type GaN contact layer 104.

Initially sapphire substrate 101 is set in a reactor of an MOCVD apparatus. Subsequently hydrogen is flown into the reactor, while the temperature of sapphire substrate 101 is increased to 1050° C. to clean a surface (a C plane) of sapphire substrate 101.

Subsequently the temperature sapphire substrate 101 is decreased to 510° C. and a carrier gas of hydrogen and source material gases of ammonium and trimethylgallium (TMG) are flown into the reactor to grow GaN buffer layer 102 on the surface (C plane) of sapphire substrate 101 by MOCVD to have a thickness of approximately 20 nm on sapphire substrate 101.

Subsequently the temperature of sapphire substrate 101 is increased to 1050° C. and a carrier gas of hydrogen, source material gases of ammonium and TMG, and an impurity gas of silane are flown into the reactor to grow Si doped, n-type GaN underlying layer 103 (carrier density: 1×10¹⁸/cm³) by MOCVD to have a thickness of 6 μm on GaN buffer layer 102.

Subsequently, similarly as done for n-type GaN underlying layer 103, n-type GaN contact layer 104 is grown by MOCVD to have a thickness of 0.5 μm on n-type GaN underlying layer 103, except that n-type GaN contact layer 104 is doped with Si to have a carrier density of 5×10¹⁸/cm³.

Subsequently the temperature of sapphire substrate 101 is decreased to 700° C. and a carrier gas of hydrogen and source material gases of ammonium, TMG and trimethylindium (TMI) are flown into the reactor to grow a 2.5 nm thick In_{0.25}Ga_{0.75}N layer and a 18 nm thick GaN layer on n-type GaN contact layer 104 alternately by six cycles in layers are grown by MOCVD to provide light emitting layer 105 having a multi quantum well structure on n-type GaN contact layer 104. It is needless to say that in depositing light emitting layer 105 when the GaN layer is grown TMI is not introduced into the reactor.

Subsequently the temperature of sapphire substrate 101 is increased to 950° C. and a carrier gas of hydrogen, source material gases of ammonium, TMG and trimethylaluminum (TMA) and an impurity gas of cyclopentadienylmagnesium (CP2Mg) are flown into the reactor to grow p-type AlGaN clad layer 106 formed of Al_{0.15}Ga_{0.85}N doped with Mg at a concentration of 1×10²⁰ atoms/cm³, by MOCVD to have a thickness of approximately 30 nm on light emitting layer 105.

Subsequently the temperature of sapphire substrate 101 is held at 950° C., while a carrier gas of hydrogen, source material gases of ammonium and TMG, and an impurity gas of CP2Mg are flown into the reactor to grow p-type GaN layer 107 formed of GaN doped with Mg at a concentration of 1×10²⁰ atoms/cm³, by MOCVD to have a thickness of 0.1 μm on p-type AlGaN clad layer 106.

Subsequently the temperature of sapphire substrate 101 is decreased to 700° C. and a carrier gas of nitrogen, source material gases of ammonium, TMG and TMI and an impurity gas of CP2Mg are flown into the reactor to grow p-type InGaN tunnel junction layer 108 formed of In_{0.25}Ga_{0.75}N doped with Mg at a concentration of 1×10²⁰ atoms/cm³, by MOCVD to have a thickness of 20 nm on p-type GaN layer 107.

Subsequently the temperature of sapphire substrate 101 is held at 700° C., while a carrier gas of nitrogen, source material gases of ammonium, TMG and TMI, and an impurity gas of silane are flown into the reactor to grow n-type InGaN tunnel junction layer 109 formed of In_{0.25}Ga_{0.75}N doped with Si at a concentration of 1×10²⁰ atoms/cm³, by MOCVD to have a thickness of 4 nm on p-type InGaN tunnel junction layer 108.

Subsequently the temperature of sapphire substrate 101 is set at a predetermined temperature between 600° C. and 900° C. and only TMI is stopped to grow n-type GaN evaporation reduction layer 110 formed of GaN doped with Si at a concentration of 1×10²⁰ atoms/cm³, to have a thickness of 15 nm on n-type InGaN tunnel junction layer 109.

Subsequently the temperature of sapphire substrate 101 is increased to 950° C. and a carrier gas of hydrogen, source material gases of ammonium and TMG, and an impurity gas of silane are flown into the reactor to grow n-type GaN layer 111 formed of GaN doped with Si at a concentration of 1×10¹⁹ atoms/cm³, by MOCVD to have a thickness of 200 nm on n-type GaN evaporation reduction layer 110.

Subsequently the temperature of sapphire substrate 101 is decreased to 700° C. and a carrier gas of nitrogen is flown into the reactor to anneal the wafer.

The annealed wafer is removed from the reactor and a mask patterned to have a predetermined shape is provided on a surface of a topmost layer, or n-type GaN layer 111, of the wafer. Reactive ion etching (RIE) is then performed to etch a portion of the wafer away, initially at n-type GaN layer 111, to expose a portion of a surface of n-type GaN contact layer 104.

Subsequently pad electrode 112 is provided on a surface of n-type GaN layer 111 and pad electrode 113 is provided on a surface of n-type GaN contact layer 104. More specifically, pad electrodes 112 and 113 are simultaneously provided by successively depositing a Ti layer and an Al layer on the surfaces of n-type GaN layer 111 and n-type GaN contact layer 104. Subsequently the wafer is divided into a plurality of chips to obtain a nitride semiconductor light emitting diode device of the first example having the structure shown in FIG. 11.

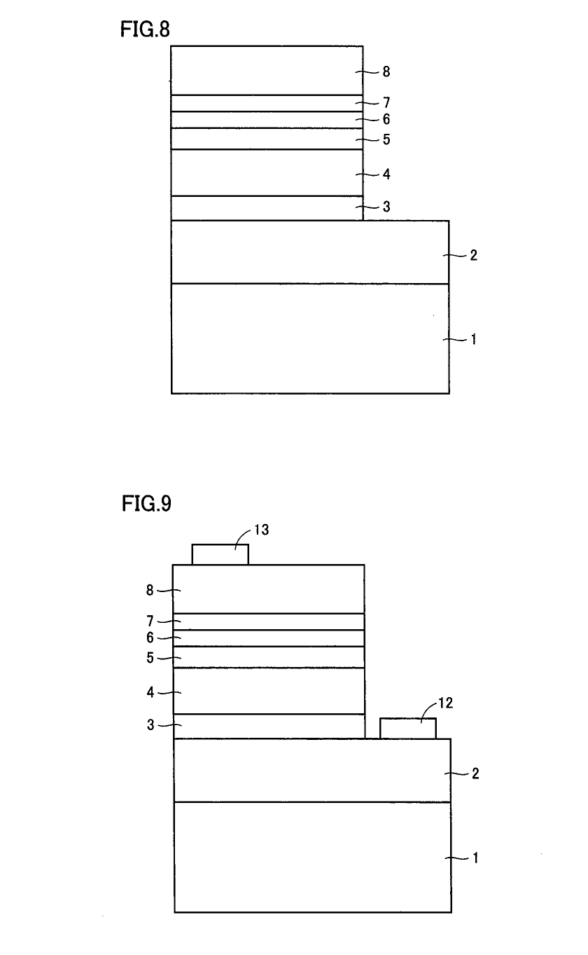

FIG. 12 shows a relationship between the temperature of sapphire substrate 101 in growing n-type GaN evaporation reduction layer 110 of the nitride semiconductor light emitting diode device of the first example and the driving voltage of the device. In FIG. 12, the vertical axis represents the driving voltage (V) at the time when a current of 20 mA is injected, and the horizontal axis represents the temperature (° C.) of sapphire substrate 101 in growing n-type GaN evaporation reduction layer 110.

As shown in FIG. 12, when the temperature of sapphire substrate 101 is 700° C., the driving voltage is the lowest value, and when the temperature of sapphire substrate 101 exceeds 850° C., the driving voltage increases drastically.

This is probably because growing n-type GaN evaporation reduction layer 110 at the temperature of the sapphire substrate 101 exceeding 850° C. (i.e., a temperature higher than 850° C., which is higher by 150° C. than 700° C., which is the temperature of sapphire substrate 101 in growing p-type InGaN tunnel junction layer 108 and n-type InGaN tunnel junction layer 109) evaporates In of p-type InGaN tunnel junction layer 108 and n-type InGaN tunnel junction layer 109 that underlie n-type GaN evaporation reduction layer 110, and thus provides a decreased probability of tunneling at the tunnel junction.

### SECOND EXAMPLE

Up to growing n-type InGaN tunnel junction layer 109, the temperature of the same conditions and method as the first example are applied.

After n-type InGaN tunnel junction layer 109 is grown, the temperature of sapphire substrate 101 is held at 700° C. and only TMI is stopped to grow n-type GaN evaporation reduction layer 110 formed of GaN doped with Si at a concentration of 1×10²⁰ atoms/cm³, by MOCVD to have a thickness of 15 nm on n-type InGaN tunnel junction layer 109.

Subsequently the temperature of sapphire substrate 101 is set at a predetermined temperature between 700° C. and 1050° C. and a carrier gas of hydrogen, source material gases of ammonium and TMG, and an impurity gas of silane are flown into the reactor to grow n-type GaN layer 111 formed of GaN doped with Si at a concentration of 1×10¹⁹ atoms/cm³, by MOCVD to have a thickness of 200 nm on n-type GaN evaporation reduction layer 110.

Subsequently the same conditions and method as the first example are applied to fabricate a nitride semiconductor light emitting diode device of the second example.

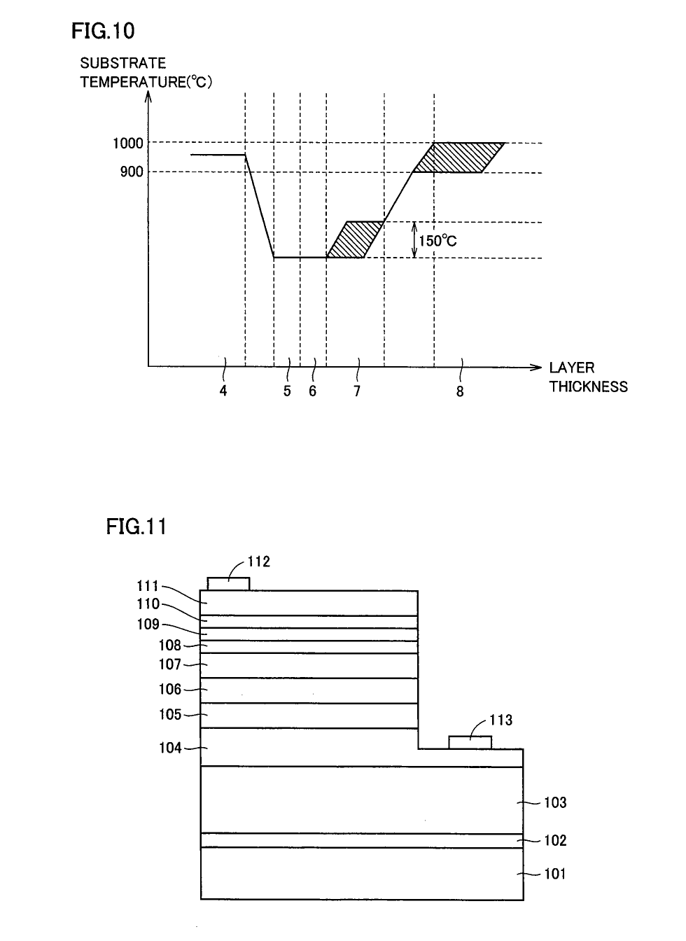

FIG. 13 shows a relationship between the temperature of sapphire substrate 101 in growing n-type GaN layer 111 of the nitride semiconductor light emitting diode device of the second example and the driving voltage of the device. In FIG. 13, the vertical axis represents the driving voltage (V) at the time when a current of 20 mA is injected, and the horizontal axis represents the temperature (° C.) of sapphire substrate 101 in growing n-type GaN layer 111.

As shown in FIG. 13, when the temperature of the substrate in growing n-type GaN layer 111 is 700° C. to 900° C., the driving voltage decreases, and when the temperature of substrate in growing n-type GaN layer 111 exceeds 900° C., the driving voltage hardly decreases.

When the temperature of sapphire substrate 101 in growing n-type GaN layer 111 ranges from 700° C. to 900° C., the driving voltage decreases. It is probably because n-type GaN layer 111 is improved in crystallinity and decreased in resistively and because in growing n-type GaN layer 111 while temperature is increased the presence of n-type GaN evaporation reduction layer 110 reduces In evaporating from p-type InGaN tunnel junction layer 108 and an activation ratio of Mg is increased.

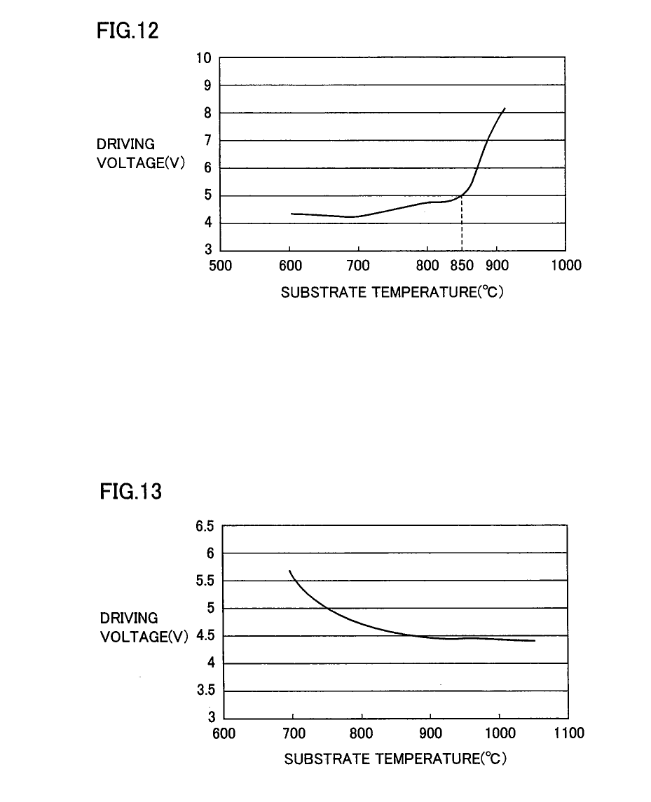

Furthermore, FIG. 14 shows a relationship between the temperature of sapphire substrate 101 in growing n-type GaN layer 111 of the nitride semiconductor light emitting diode device of the second example and the optical output of the device. In FIG. 14 the vertical axis represents the optical output by a relative value and the horizontal axis represents the temperature (° C.) of sapphire substrate 101 in growing n-type GaN layer 111.

As shown in FIG. 14, when the temperature of sapphire substrate 101 in growing n-type GaN layer 111 is from 700° C. to 1000° C., an optical output is substantially constant, and when the temperature of sapphire substrate 101 in growing n-type GaN layer 111 exceeds 1000° C., an optical output is significantly reduced. This is probably because when the temperature of sapphire substrate 101 in growing n-type GaN layer 111 exceeds 1000° C., light emitting layer 105 impairs in crystallinity and thus emission efficiency reduces.

From the above result it has been found that the temperature of sapphire substrate 101 in growing n-type GaN layer 111 is preferably at least 900° C. and at most 1000° C.

### THIRD EXAMPLE

Up to growing p-type InGaN tunnel junction layer 108, the same conditions and method as the first example are applied.

After p-type InGaN tunnel junction layer 108 is grown, the temperature of sapphire substrate 101 is held at 700° C. and only TMI is stopped to grow n-type GaN evaporation reduction layer 110 formed of GaN doped with Si at a concentration of 1×10²⁰ atoms/cm³, by MOCVD to have a thickness of 0 nm to 15 nm on p-type InGaN tunnel junction layer 108.

Subsequently the same conditions and method as the first example are applied to fabricate a nitride semiconductor light emitting diode device of the third example.

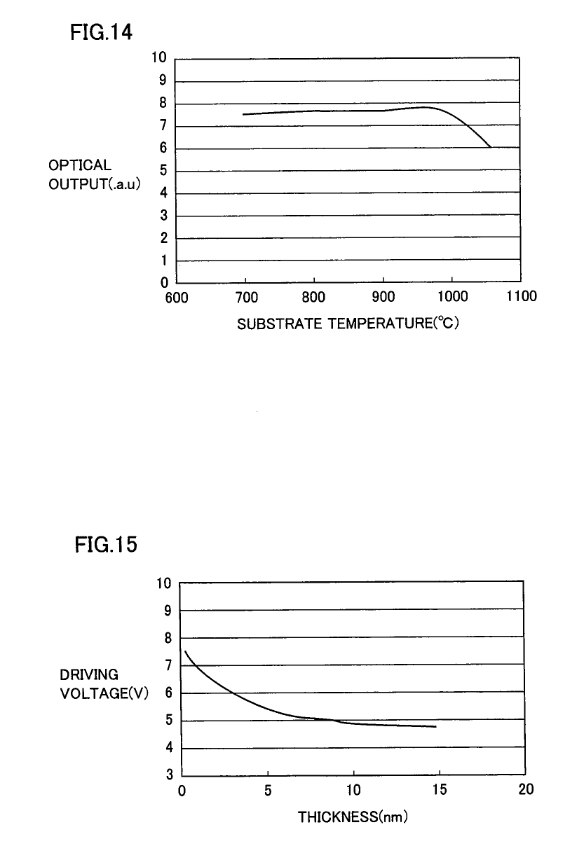

FIG. 15 shows a relationship between the thickness of n-type GaN evaporation reduction layer 110 of the nitride semiconductor light emitting diode device of the third example and the driving voltage of the device. In FIG. 15, the vertical axis represents the driving voltage (V) at the time when a current of 20 mA is injected, and the horizontal axis represents n-type GaN evaporation reduction layer 110 in thickness (nm).

As shown in FIG. 15, it has been found that the driving voltage drastically increases when n-type GaN evaporation reduction layer 110 has a thickness smaller than 5 nm. This is probably because with n-type GaN evaporation reduction layer 110 having a thickness smaller than 5 nm, the In of p-type InGaN tunnel junction layer 108 and that of n-type InGaN tunnel junction layer 109 evaporate in a temperature elevation process provided after n-type GaN evaporation reduction layer 110 is grown.

The present invention can thus achieve a reduced driving voltage of a nitride semiconductor light emitting diode device or a similar nitride semiconductor light emitting device having a tunnel junction and emitting blue light (for example having a wavelength of at least 430 nm and at most 490 nm), and also allows the device to extract light more efficiently.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of fabricating a nitride semiconductor light emitting device, comprising the steps of
depositing on a substrate a first n-type nitride semiconductor layer, a light emitting layer, a p-type nitride semiconductor layer, and a p-type nitride semiconductor tunnel junction layer containing indium, in this order;
depositing a nitride semiconductor evaporation reduction layer on said p-type nitride semiconductor tunnel junction layer at the temperature of said substrate which is at most a temperature higher by 150° C. than that of said substrate in depositing said p-type nitride semiconductor tunnel junction layer, said nitride semiconductor evaporation reduction layer having a band gap larger than that of said p-type nitride semiconductor tunnel junction layer; and
depositing a second n-type nitride semiconductor layer on said nitride semiconductor evaporation reduction layer at the temperature of said substrate which is a temperature higher than that of said substrate in depositing said nitride semiconductor evaporation reduction layer.

2. The method of fabricating a nitride semiconductor light emitting device, according to claim 1, wherein an n-type nitride semiconductor tunnel junction layer is deposited on said p-type nitride semiconductor tunnel junction layer to cooperate therewith to form a tunnel junction and said nitride semiconductor evaporation reduction layer is thereafter deposited on said n-type nitride semiconductor tunnel junction layer.

3. The method of fabricating a nitride semiconductor light emitting device, according to claim 1, wherein said second n-type nitride semiconductor layer is deposited at the temperature of said substrate which is at least 900° C. and at most 1000° C.

4. The method of fabricating a nitride semiconductor light emitting device, according to claim 1, wherein said nitride semiconductor evaporation reduction layer is at least 5 nm in thickness.
